(19) United States
(12) Patent Application Publication
(10) Pub. No.: US 2025/0100422 A1
(43) Pub. Date: Mar. 27, 2025

(54) BATTERY MODEL CALIBRATION FOR ELECTRIC VEHICLES

(71) Applicant: Joby Aero, Inc., Santa Cruz, CA (US)

(72) Inventors: Ruxiu Zhao, Campbell, CA (US); Alireza Goshtasbi, San Jose, CA (US); Sangwoo Han, Sunnyvale, CA (US); David Locascio, Indianapolis, IN (US); Jeremy Neubauer, Mountain View, CA (US)

(21) Appl. No.: 18/896,387

(22) Filed: Sep. 25, 2024

Related U.S. Application Data
(60) Provisional application No. 63/585,197, filed on Sep. 25, 2023.

(51) Int. Cl. B60L 58/18; G01R 31/00; G01R 31/367; G01R 31/3842; G06F 30/15

(52) U.S. Cl. CPC B60L 58/18; G01R 31/008; G01R 31/367; G01R 31/3842; G06F 30/15; B60L 2200/10

(57) ABSTRACT

Example methods calibrate battery models in electric aircraft using closed-loop feedback. Test points gaps are received. The aircraft connects to ground support equipment (GSE) and is immobilized. Certain battery packs are selected for testing. Propellers are ramped to create power draws per a test plan while monitoring voltage, current, and temperature telemetry. Selective battery packs are activated to focus loads. Telemetry data is processed and stored. Rest periods allow battery temperature stabilization between test points. Additional packs are tested if needed. Battery models are updated by analyzing telemetry data. Overall, the method maintains customized, accurate battery models using lab testing and in-situ calibration with the GSE. Frequent and ongoing recalibration via closed-loop feedback replaces assumptions with observed data for high-fidelity state-of-health predictions throughout the battery lifetime.

### CROSS-REFERENCE TO RELATED APPLICATION

This patent application claims the benefit of U.S. Provisional Patent Application No. 63/585,197, filed Sep. 25, 2023, which is incorporated by reference herein in its entirety.

### BACKGROUND

Electric vehicles, such as electric vertical takeoff and landing (eVTOL) aircraft, are an emerging technology that faces unique challenges as compared to conventional vehicles. One such challenge, for example relating to electric aircraft, is accurately predicting aircraft range for a given flight profile. Range directly impacts both safety and usability.

Range predictions and several other operations rely on battery models for a given battery that forecast cell voltage response and capacity fade over time. However, lithium-ion cells, which are commonly used in electric aircraft, exhibit highly nonlinear degradation patterns that are difficult to model. Degradation rates depend on complex interactions between usage history, power demand, state of charge, temperature, and other factors.

Furthermore, eVTOL batteries often operate closer to performance limits than conventional electric vehicle (EV) batteries. The high power draw combined with limited cell cooling places more stress on cells and leads to rapid, nonlinear aging. This makes battery modeling more difficult.

For certification, the Federal Aviation Administration (FAA) requires demonstrating extremely low catastrophic failure rates. Battery failure is a leading risk factor. Accurately modeling worst-case cell performance is of course helpful in addressing this risk factor. However, nominal flight data is insufficient to characterize corner case conditions.

EV batteries, such as those used on electric aircraft, may benefit from battery models that can capture complex, nonlinear degradation while providing conservative estimates of worst-case performance.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 is a schematic diagram illustrating ground support equipment (GSE), according to some examples, which may provide charging and other support services to multiple electric aircraft.

FIG. 2 is a block diagram showing further details regarding the components and architecture of the electric aircraft and the monitoring and control center that may implement a closed-loop calibration process for one or more battery models, according to some examples.

FIG. 3 is a flowchart illustrating an example high-level method to initialize and then calibrate various battery models.

FIG. 4 is a flowchart illustrating an example method according to some examples.

FIG. 5 is a flowchart illustrating a method 500, according to some examples, providing further details regarding operations that may be performed in FIG. 4.

FIG. 6 is a flowchart illustrating the calibration procedure, according to some examples.

FIG. 7 is a plan view of a vertical takeoff and landing (VTOL) aircraft according to some examples, which may comprise an electric aircraft.

FIG. 8 is a schematic view of an aircraft energy storage system, according to some examples.

FIG. 9 illustrates a diagrammatic representation of a machine in the form of a computer system within which a set of instructions may be executed for causing the machine to perform any one or more of the methodologies discussed herein, according to some examples.

### DETAILED DESCRIPTION

The examples disclosed herein relate to systems and methods for maintaining accurate battery models in electric aircraft through a closed-loop calibration process using ground support equipment.

As lithium-ion battery packs age during real-world flight operations, their capacity and power capabilities degrade in a nonlinear fashion. Initial battery models may be developed using extensive lab testing and historical degradation data. However, once in service, actual degradation patterns may diverge from assumptions.

To address this, some examples provide a calibration procedure that uses rapid charging and thermal management ground support equipment designed for electric aircraft. With the aircraft immobilized and connected to the GSE, controlled load profiles are applied to the batteries using the aircraft's own propulsion system. The GSE provides stable and safe testing conditions.

Voltage, current, and temperature telemetry is continuously monitored during testing. The data provides insights into cell performance and degradation characteristics. Sophisticated algorithms then update the battery models to match measured behavior rather than relying on assumptions.

By frequently recalibrating the models, the closed-loop calibration process maintains high-fidelity predictions throughout service life. The combination of lab testing and in-situ calibration enables robust state-of-health tracking across the battery lifetime.

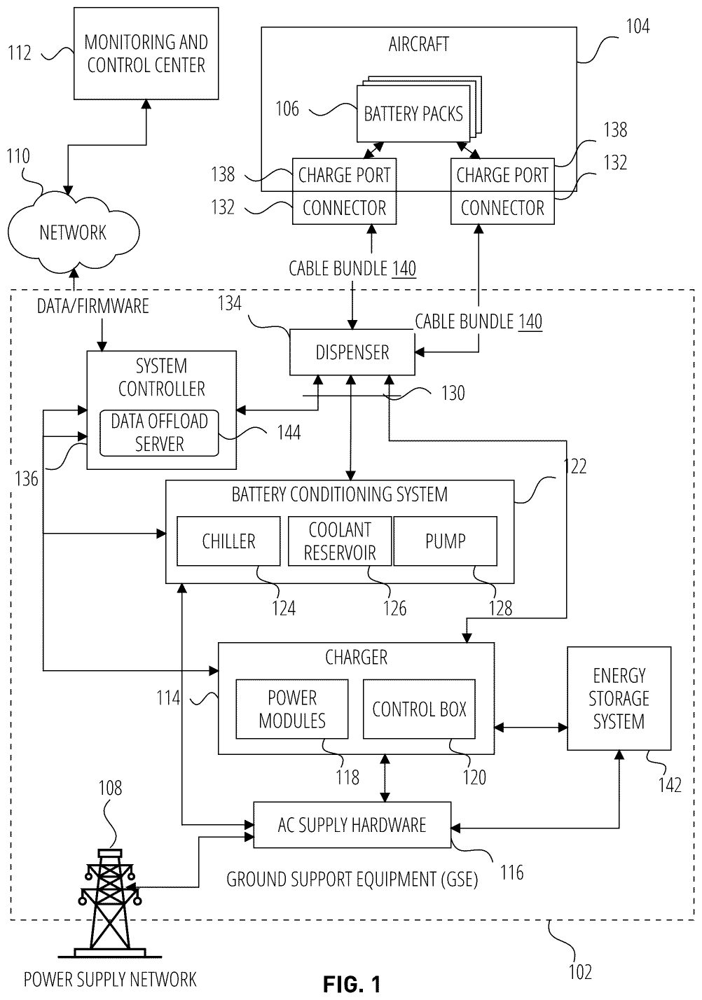

FIG. 1 is a schematic diagram illustrating ground support equipment (GSE) 102, according to some examples, which may provide charging and other support services to multiple electric aircraft 104. The GSE 102 facilitates rapid charging of one or more battery packs 106 of the electric aircraft 104. The GSE 102 contains several components that are described below.

The GSE 102 connects via a grid connection to an electrical grid or power supply network 108 and via a network 110 to a monitoring and control center 112. The monitoring and control center 112 oversees charging operations for a plurality of the electric aircraft 104 by the GSE 102

A charger 114 receives electrical charge from the power supply network 108 via AC supply hardware 116 and distributes it to charge the battery packs 106 of the electric aircraft 104. The charger 114 contains multiple power modules 118 to independently charge each of battery packs 106. A control box 120 coordinates the power modules 118. The charger 114 has a modular architecture that can be configured for different aircraft battery configurations.

A battery conditioning system 122 thermally conditions the battery packs 106 during charging. It contains a chiller 124 that chills a coolant fluid stored in a coolant reservoir 126. One or more pumps 128 circulate the coolant from the coolant reservoir 126, through hoses that form part of a cable bundle 130, to an internal cooling system of the electric aircraft 104 via connectors 132 (e.g., charge handles). This shared coolant loop enables fast battery cooling during charging.

One or more dispensers 134 provide structural support and contain or are coupled to one or more system controllers 136 that regulate the power and coolant flow to the connectors 132 based on need. The connectors 132 connect to one or more charge ports 138 of the electric aircraft 104 to exchange data, charge, and coolant between the GSE 102 and the electric aircraft 104. For example, the cable bundle 130 routes power, coolant, and data connections from the charger 114, chiller 124, and coolant reservoir 126 to the dispensers 134 and the connectors 132. Additional cable bundles 140 extend the connections to the connectors 132.

The system controller 136 monitors and controls the components of the GSE 102 to exchange data, charge, and coolant to the electric aircraft 104, while maintaining safe operating temperatures and conditions. It coordinates the charging processes based on battery feedback.

A data offload server 144 may form part of the system controller 136 and operatively collects data related to the charging operations, including telemetry data from the electric aircraft 104, status data from the GSE 102 components like the battery conditioning system 122, and data on the charging sessions. The data offload server 144 stores and aggregates the data it collects from the various GSE 102 subsystems and the electric aircraft 104. The data offload server 144 can offload or transfer the charging operations data it collects to other systems for monitoring, analytics, scheduling, and other applications. This may include offloading to the monitoring and control center 112.

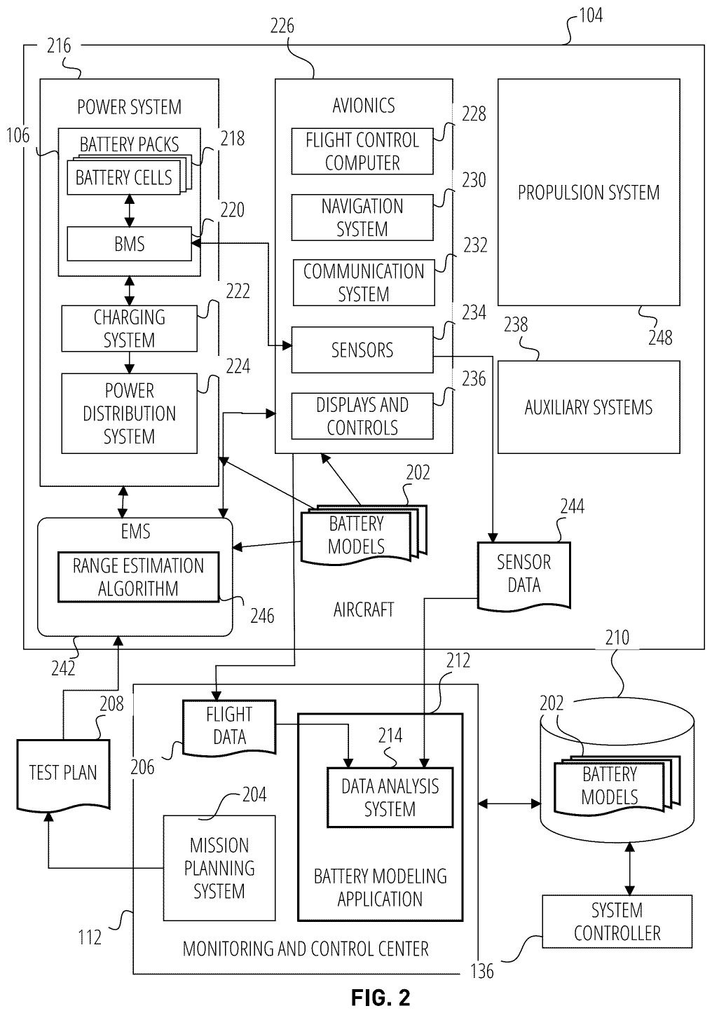

FIG. 2 is a block diagram showing further details regarding the components and architecture of the electric aircraft 104 and the monitoring and control center 112 that may implement a closed-loop calibration process for one or more battery models 202, according to some examples.

Referring to FIG. 2, the monitoring and control center 112 includes a mission planning system 204 and a data analysis system 214. The mission planning system 204 analyzes flight data 206 regarding battery parameters and performance and generates battery test plans 208.

The mission planning system 204 utilizes processors and data storage 210 to run a battery modeling application 212. The data analysis system 214 processes data from calibration tests and updates the battery models 202. The mission planning system 204 includes processors to execute the battery modeling application 212, which includes model update algorithms to access and update the battery models 202.

The electric aircraft 104 includes propulsion system 248 having distributed electric motors, controllers, and propellers that provide controlled thrust in both vertical and forward flight configurations based on commands from flight control computers 228 and electric power from the battery packs 106. The electric aircraft also includes a power system 216 including that includes the multiple isolate battery packs 106, each of which comprises multiple battery cells 218 and a battery management system (BMS) 220.

The electric aircraft 104 further includes a charging system 222 that recharges the battery packs 106 by connecting to the charger 114. The charging system 222 regulates and distributes the electrical current from a ground support equipment charger 114 or other charging source to safely charge the battery packs 106. The charging system 222 works closely with the BMS 220 of the battery packs 106 to coordinate charging and ensure the safety and longevity of the battery packs 106. The electric aircraft 104 also includes a power distribution system 224 that takes the power output from the battery packs 106 and distributes it in a controlled, fault-protected manner to the propulsion system 248 and other aircraft components based on commands from an energy management system (EMS) 242.

The electric aircraft also include a variety of avionics 226, including one or more flight control computers 228, a navigation system 230, and a communication system 232. The flight control computers 228 run flight control system software and algorithms. They receive sensor data 244 from sensors 234 and navigation data from the navigation system 230, process this sensor data 244 and navigation data, and output commands to flight control actuators like ailerons, rudders, and propulsion systems. The flight control computers 228 coordinate with the EMS 242, communication system 232, and other avionics to control and monitor the electric aircraft 104 during flight.

The navigation system 230 enables the electric aircraft 104 to determine and maintain its position, orientation, and trajectory during flight. It includes sensors such as global positioning system (GPS) receivers, inertial measurement units (IMUs), and air data systems. These sensors feed data to navigation computers that run sensor fusion algorithms to produce an accurate navigation solution. The navigation system 230 provides the aircraft's geodetic position, altitude, attitude, heading, velocity, and other key parameters. The navigation system 230 supplies data to the flight control computers 228 and other avionics systems that need positioning data. Advanced navigation systems may incorporate features like terrain mapping, traffic avoidance, and flight path optimization. The electric aircraft also includes displays and controls 236.

The EMS 242 oversees storage and distribution of electrical energy on the electric aircraft 104. It monitors the battery packs 106 and controls the charging system 222 and power distribution system 224 to ensure proper power utilization across phases of flight. The EMS 242 contains power management electronics and runs advanced algorithms to balance energy storage/delivery across packs, enhancing reliability. It provides battery state monitoring and charge control during ground operations and dispatches power during flight based on current demand. The EMS 242 further integrates energy usage data with flight telemetry to make informed distribution decisions. Auxiliary systems 238 include, for example, climate controls, lighting, and passenger accommodations.

In operation, the mission planning system 204 analyzes flight data 206 for the electric aircraft 104 and generates battery test plans 208 based on modeling requirements. The test plans 208 are provided to the EMS 242. The EMS 242 then tests the battery packs 106 according to the test plan 208 by charging or discharging using a power supply of the power distribution system 224. Alternatively, the propulsion system is used for charging or discharging (as will be described below) while monitoring the battery packs 106 with the sensors 234 and the respective BMS 220.

The sensor data 244 is returned to the data analysis system 214, which processes sensor data 244 to obtain analyzed results, and then uses the analyzed results to update the battery models 202. The updated battery models 202 are supplied back to the mission planning system 204 to improve modeling fidelity. This closed-loop process between the monitoring and control center 112 of the GSE 102 enables data-driven battery modeling to continuously maintain accuracy under real-world operating conditions.

In addition to the closed-loop process described above, the monitoring and control center 112 may provide updated battery models 202 directly to the electric aircraft 104, where they are maintained in non-volatile storage 210 for access by various systems. For example, a range estimation algorithm 246 executed on the EMS 242 or the flight control computers 228 can leverage the models to more accurately predict remaining flight range based on up-to-date battery state of health parameters and cell chemistry data.

The range estimation algorithm 246 may access the model data via a high-speed avionics data bus while the electric aircraft 104 is in flight. The power system 216 may use the model data to optimize electrical load scheduling across the battery packs 106 based on the unique impedance, capacity, and health characteristics of each pack modeled. The charging system 222 of the power system 216 may tune charge termination criteria per pack to maximize cycle life based on cell impedance growth and charge voltage characteristics in the model.

Further, the BMS 220 may run model-based diagnostics tracking cell capacity fade, power fade, and impedance growth trends for early fault detection. Across various subsystems, multiple model data parameters may be consumed to optimize battery utilization. By propagating the calibrated battery models 202 across both the GSE 102 and electric aircraft 104, the battery modeling application 212 enables the models' practical application across charging, maintenance, and flight operations to maximize battery health, safety, and performance.

Several types of battery models may be included in the battery models 202, such any combination of one or more of the following. Electrochemical models, which are physics-based models simulate the electrochemical processes within a battery cell. Examples include equivalent circuit models (ECMs), Pseudo 2-Dimensional (P2D) models, pore models, and molecular/atomistic models. Empirical models, which characterize the battery's behavior using experimental data and mathematical equations. Examples include Rint/RC models, runtime-based models, and neural network models. Analytical models, which use simplified physics along with empirical data to balance complexity and accuracy. Examples include the kinetic battery model, enhanced self-correcting model, and single particle model.

Specific examples that may be included in the battery models 202 that are discussed in further detail below include pseudo 2-dimensional (P2D) models and equivalent circuit models (ECMs). The P2D models may use porous electrode theory to model battery dynamics with enhanced physics compared to ECMs. The ECM models use electrical components like capacitors, resistors, and voltage sources to model battery dynamics. ECMs may be used for real-time estimation. The battery models 202 may further use a hybrid modeling approach combining elements of multiple model types to maximize accuracy throughout the battery's lifespan. The models are customized for the battery chemistry and cell design.

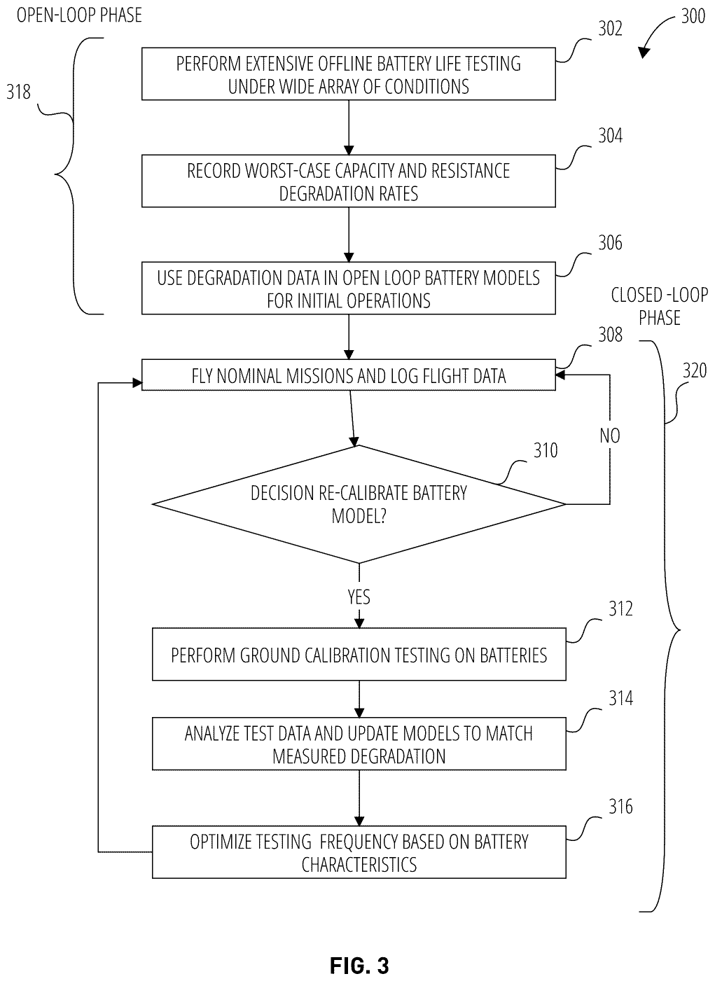

FIG. 3 illustrates an example high-level method 300 to initialize and then calibrate the various battery models 202. Although the example method 300 depicts a particular sequence of operations, the sequence may be altered without departing from the scope of the present disclosure. For example, some of the operations depicted may be performed in parallel or in a different sequence that does not materially affect the function of the method 300. In other examples, different components of an example device or system that implements the method 300 may perform functions at substantially the same time or in a specific sequence.

Referring to FIG. 3, the method 300 may be divided into two main phases: (1) an open-loop phase 318; and (2) a closed-loop phase 320. Open loop modeling involves creating a model of the battery based only on its design parameters and inputs, without any feedback. The model makes predictions about the battery's behavior and state (e.g. voltage, current, temperature) based solely on driving inputs like current draw. It does not correct or update the model based on comparing predictions to actual measurements. Open loop models are simpler but may become less accurate over time as errors accumulate.

In closed-loop modeling, real-world operating data may be used as feedback to refine the model output. As battery data may be measured in-situ, it is used to update the models to reflect the actual state of health and performance. This customizes the models to match measured metrics instead of relying solely on assumptions. The closed-loop phase tunes the models to minimize errors between predictions and observations.

The method 300, in some examples, leverages both modeling approaches. Open-loop models provide safe baseline estimates while closed-loop models increase accuracy by calibrating to measured degradation. The combination allows robust and reliable modeling throughout battery lifetime.

In the open-loop phase 318, extensive offline battery life testing is performed under a wide array of conditions at block 302. This testing covers several factors like temperature, depth of discharge, charge rate, etc. using lab equipment to induce battery aging. The worst-case capacity and resistance degradation rates from this testing are then recorded by the battery modeling application 212 at block 304. These established degradation profiles are used by the onboard battery models 202 to make initial state-of-health and range predictions at block 306. Using predetermined degradation rates provides a conservative estimate of battery life.

Proceeding to the closed-loop phase 320, at block 308, once vehicles are in service, the EMS 242 and sensors 234 log relevant flight data during nominal missions. This real-world operating data is analyzed by the mission planning system 204 to decide if battery models 202 need recalibration at decision block 310.

If recalibration is deemed necessary, the method 300 proceeds to block 312. If not, the method 300 returns to block 308.

At block 312, the EMS 242 performs ground calibration testing on the batteries by applying controlled load profiles, for example, using the propulsion system 248 and power distribution system 224. The load profiles target different power levels, temperatures, and charge states based on test plans 208 from the mission planning system 204. At block 314, test data is analyzed by the data analysis system 214 to update the battery models 202 to match measured degradation rather than relying on predetermined rates. This improves model fidelity. Finally, the mission planning system 204 may seek to optimize the overall testing frequency based on battery characteristics like chemistry and usage to maximize efficiency at block 316. For example, testing may be more frequent early in life when degradation rates are higher. This closed-loop phase 320 continually improves model accuracy by replacing assumptions with real-world data. The end results are customized battery models 202 that reflect an actual state of health and performance.

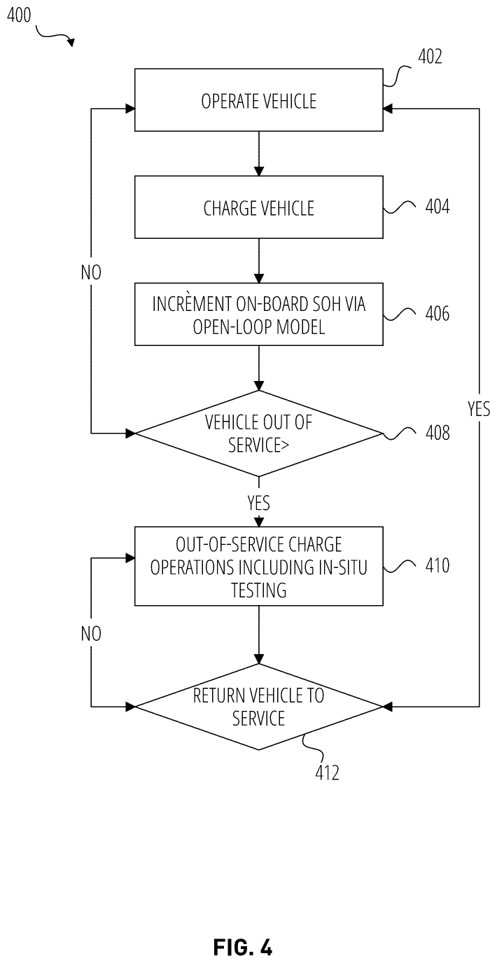

FIG. 4 illustrates an example method 400, according to some examples. The method 400 can be divided into two main phases—an open-loop phase and a closed-loop phase. In the open-loop phase, the electric aircraft 104 is operated on missions at block 402. After flights, the GSE 102 charges the electric aircraft 104 at block 404. During charging, at block 406, state-of-health (SoH) of the battery packs 106 as reflected by the onboard battery models 202 is updates and incremented. The open-loop model applies predetermined degradation rates based on extensive lab testing using the battery modeling application 212. This provides conservative estimates of battery health.

Once the electric aircraft 104 has been in service for some time, the EMS 242 may take the electric aircraft 104 out of service (OOS) for maintenance at decision block 408. While OOS, the EMS 242 may perform further OOS (e.g., overnight) charging operations GSE 102 at block 410. For example, in-situ calibration testing may be done by applying controlled load profiles to the battery packs 106 using the propulsion system 248 and power distribution system 224 of the electric aircraft 104.

After maintenance is complete, the EMS 242 returns the electric aircraft 104 to service at decision block 412. Before returning to flight, the mission planning system 204 may load updated battery models 202 onto the electric aircraft 104. The data analysis system 214 updates the models based on data measured during testing at block 410 to customize predictions to the actual degradation experienced.

In summary, the onboard battery models 202 provide initial SoH estimates using the open-loop model. Periodic calibration testing is then used to tune the models in a closed-loop manner using the GSE 102. This improves estimation accuracy as the battery packs 106 age in service. The combination of open-loop and closed-loop modeling allows robust SoH monitoring throughout the battery lifetime.

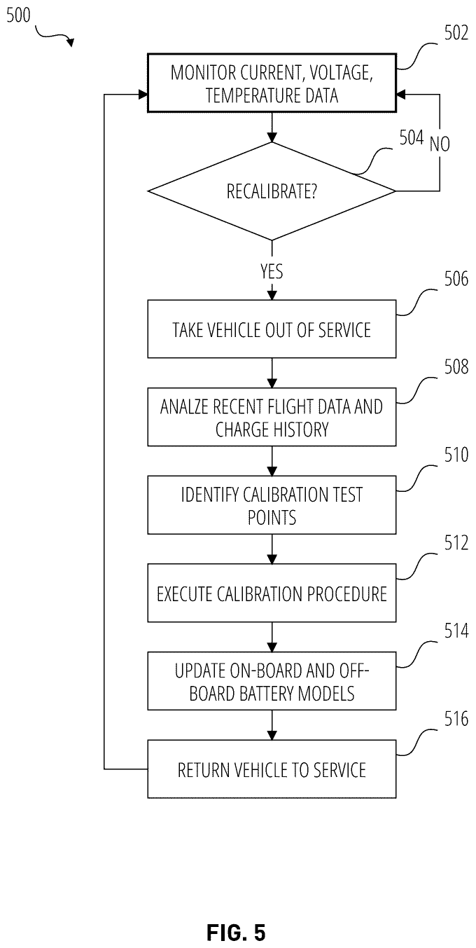

FIG. 5 is a flowchart illustrating a method 500, according to some examples, providing further details regarding operations that may be performed at decision block 408 and block 410 of FIG. 4. During normal operation, the sensors 234 and BMS 220 monitor current, voltage, and temperature data for the battery packs 106 at block 502. This data is included in flight data 206 and sensor data 244 provided by the avionics 226 (e.g., the flight control computer 228) to the data analysis system 214 when telemetric data is offloaded by the data offload server 144 to the GSE 102 during a charging operation.

At decision block 504, the data analysis system 214 analyzes the data to determine if battery model recalibration is necessary or recommended. If recalibration is needed, the monitoring and control center 112 takes the electric aircraft 104 out of service at block 506. At block 508, the data analysis system 214 analyzes recent flight data 206 and charge history to determine operating conditions that have not yet been covered by calibration testing. For example, the flight data 206 is statistically analyzed to evaluate coverage of tested versus untested conditions across factors like temperature, power level, state of charge, charge/discharge, and degradation.

For the temperature factor, the flight data is examined to find temperature ranges that have not been tested during calibration. For example, if all testing so far has been from 10-30° C., a test point may be added at 40° C. for the power level factor, the power profile is analyzed to identify high power demands in the flight data that exceed levels tested in the lab. Test points can then target those higher loads. For the state of charge (SOC) factor, the SOC range is evaluated to find portions of the normal operating window that have not been calibrated. Test points can focus on those SOC regions. For the charge/discharge factors, flight data 206 can indicate if charging or discharging has not been sufficiently tested. Specific test points may be added to target charge and discharge as needed. And for the degradation factor, test points can target operating conditions that are expected to induce higher stress and degradation rates. By statistically analyzing flight data across one or more of these factors in any combination, the data analysis system 214 identifies gaps in calibration coverage. Test points are then selected by the battery modeling application 212 to target those regions and conditions that have not yet been calibrated.

At block 510, the battery modeling application 212 identifies specific calibration test points that target uncovered operating conditions. For example, the battery modeling application 212 may leverage statistical analysis techniques to strategically identify optimal calibration test points that will maximize modeling improvements. To this end, the recent flight data 206 may be divided into bins based on key factors like temperature, power level, state of charge, and whether charging or discharging. The amount of data in each bin may be tallied to reveal operating conditions that have been rarely encountered during flights. Statistical hypothesis testing determines if any bins have significantly lower counts than expected by random chance, indicating a gap in the flight data.

These sparse bins are prioritized for test point selection, as they represent uncommon operating conditions in real-world flights. Within each bin, the design of experiment techniques systematically picks combinations of temperature, power level, state of charge, and charge/discharge to cover the space efficiently. Interactions between factors may be modeled using regression analysis to predict degradation rates for each combination. By leveraging these statistical analysis approaches, the battery modeling application 212 may identify specific gaps in the flight data and then select calibration test points to target those regions.

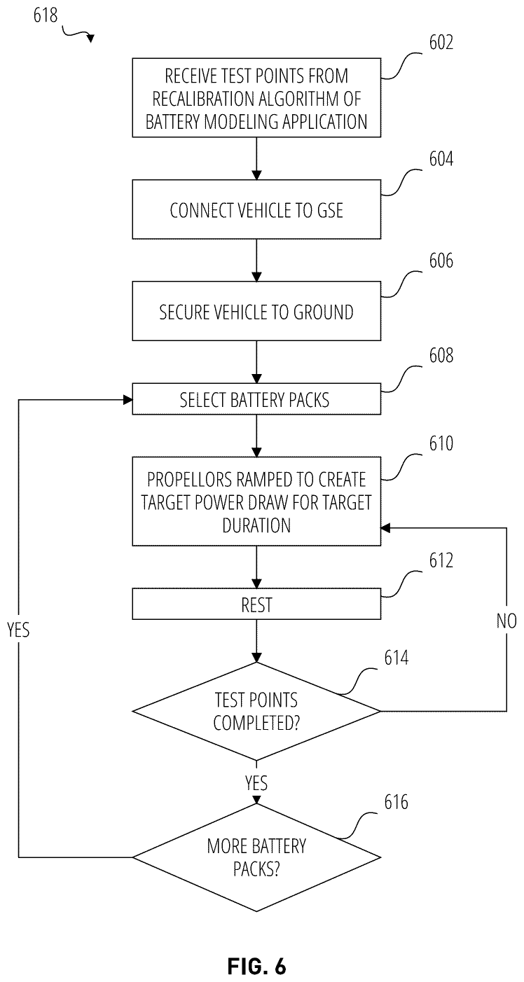

Also at block 510, the battery modeling application 212 then creates and uploads a test plan 208 to the EMS 242, the test plan embodying a calibration procedure and including the specified test points. The EMS 242 then executes the calibration procedure at block 512 by applying load profiles specified in the test plan 208 to the battery packs 106 using the propulsion system 248 and power distribution system 224, as described below with reference to FIG. 6.

The data analysis system 214 processes data collected during the calibration tests and passes the analysis results to the battery modeling application 212. The battery modeling application 212 then updates the battery models 202, both onboard and offboard, at block 514. After the models are updated, the monitoring and control center 112 returns the electric aircraft 104 to service at block 516.

FIG. 6 is a flowchart illustrating the calibration procedure 618, according to some examples. The calibration procedure 618 seeks to maintain accurate battery models and SOH estimations for the electric aircraft 104. As the lithium-ion battery packs 106 age during real-world flight operations, their capacity and power capabilities degrade in a nonlinear fashion. To track these changes, initial battery models 202 are developed using extensive lab testing and historical degradation data. However, once in service, the actual degradation patterns may diverge from assumptions. The calibration procedure provides closed-loop feedback using field data.

The calibration procedure 618 begins at block 602 by receiving test points from the recalibration algorithm of the battery modeling application 212. The recalibration algorithm analyzes recent flight data 206 collected during normal operations to determine if battery model recalibration is necessary. The flight data 206 includes current, voltage, and temperature measurements from sensors 234 and BMS 220.

If recalibration is needed, the data analysis system 214 further analyzes the flight data 206 to identify gaps in calibration coverage across factors like temperature, power level, state of charge (SOC), and charge/discharge. For example, the flight data is divided into bins based on these factors and analyzed to find bins with low data counts, indicating untested conditions.

The battery modeling application 212 then identifies specific test points targeting these uncovered operating conditions. It may use statistical analysis techniques like design of experiments to efficiently cover the gaps. Interactions between factors are modeled using regression analysis to predict degradation rates for each combination of conditions. This allows the modeling application 212 to strategically select optimal calibration test points that will maximize improvements to the battery models 202. The test points specifying combinations of temperature, power, and SOC are then provided to the calibration procedure 618 at block 602.

At block 604, the procedure includes connecting the electric aircraft 104 to specialized GSE 102 designed for rapid charging and thermal management. The GSE 102 contains a charger 114 to charge multiple, isolated battery packs 106 simultaneously. It also has a shared cooling loop that circulates chilled coolant to the aircraft's internal cooling system, enabling fast in-situ battery cooling. With the vehicle immobilized, the GSE 102 provides a stable test platform.

The calibration procedure 618 further includes securing the electric aircraft 104 to the ground at block 606 to prevent movement during testing. This may be accomplished by using tie-downs, wheel chocks, and/or other restraint mechanisms. For example, sturdy straps or cables could be attached to hard points on the aircraft's landing gear and secured to anchors on the ground. The straps distribute load across the landing gear structure to immobilize the electric aircraft 104. Additionally, chocks could be placed in front and behind the wheels on the landing gear. The chocks are wedges that prevent the electric aircraft 104 from rolling forward or backward. They provide redundant restraint in conjunction with the tie-downs. The electric aircraft 104 may also be situated on jack stands or supports that elevate it off the ground. With the landing gear and aircraft weight supported, the wheels can be completely immobilized for testing. Securing the electric aircraft 104 properly prevents unintended movement of control surfaces or propellers during calibration. This maintains a safe test environment and ensures loads are applied in a controlled manner. Completely restraining the electric aircraft 104 provides a stable platform from which accurate and repeatable data can be obtained. The restraint mechanisms keep the electric aircraft 104 fixed throughout lengthy calibration procedures.

At block 608, the energy management system (EMS) 242 selects particular battery packs 106 to test based on the calibration test plan 208 generated by the battery modeling application 212. The test plan 208 specifies which battery packs 106 should be tested and in what order based on factors like battery age, usage history, and previous test coverage. For example, the test plan 208 may prioritize testing older packs that have experienced more degradation. The test plan 208 may also focus on packs that have not yet been tested across the full range of operating conditions. By intelligently selecting packs, the EMS 242 can maximize the impact of calibration testing on modeling accuracy.

At block 610, propellers are ramped up and down by the propulsion system 248 to create target power draws for specified durations. The propulsion system 248 includes electric motors connected to the propellers. By varying the motor torque and RPM, different thrust levels can be achieved. For example, to reach a high power draw, the motors and propellers may be rapidly accelerated to produce maximum thrust. The propellers essentially become a dynamic load bank, drawing significant amounts of current from the battery packs 106. Conversely, to drop to a lower power level, the motor torque can be reduced to decrease RPM and thrust. The propulsion system 252 can thus precisely control power by modulating motor output.

The EMS 242 determines which battery packs 106 are activated during testing. This allows certain packs to be selectively discharged to focus the electrical load. For example, two out of six total packs may be turned on to double the current draw versus discharging all packs simultaneously.

The BMS 220 and sensors 234 continuously monitor voltage, current, and temperature telemetry during the power profile. The sensors 234 may include shunt resistors to measure pack and cell-level currents. Voltage taps installed at terminals may provide pack and cell voltage data. Thermocouples, thermistors, or other temperature sensors may track thermal behavior. The BMS 220 aggregates and processes the raw data from sensors 234. This may include filtering, calibration, and data buffering. The BMS 220 transmits processed sensor measurements via a vehicle communication bus to a flight computer or data acquisition system. Time-stamped current, voltage, and temperature data synchronized across all battery packs 106 is logged to persistent storage for later analysis. This high-resolution profile of electrical and thermal behavior under load conditions provides insights into cell performance and degradation characteristics.

The calibration procedure 618 allows for resting periods at block 612 between test points to allow the battery temperature to stabilize. Applying high electrical loads during testing inevitably heats up the battery packs 106. The resting periods provide time for the packs to cool back down through natural convection/radiation and the GSE's 102 cooling system. Allowing temperature to stabilize before proceeding ensures the next test point begins at a controlled temperature. This provides consistency between results at different set points. The duration of the rest periods may be predetermined based on battery size and chemistry. Alternatively, the procedure may check pack temperatures with sensors 234 and end the rest period when readings drop below a threshold. In either case, the rests let packs fully cool between tests for safety and data integrity.

At decision block 614, the EMS 242 checks if all test points have been completed. If not, calibration procedure 618 returns to block 610 to continue testing. If test points remain for other battery packs 106, the calibration procedure 618 moves to decision block 616 to determine if more battery packs 106 need to be tested. If so, it loops back to block 608 to select the next battery pack 106. If all test points are complete for all battery packs 106 to be tested, the calibration procedure 618 ends.

The resulting performance data validates degradation differences between the battery packs 106. For example, impedance growth or capacity fade may diverge from initial assumptions. The EMS 242 provides this data to the GSE 102 for model tuning. Sophisticated algorithms update model parameters to match measured behavior by leveraging techniques like Bayesian inference.

By frequently recalibrating the battery models 202, the calibration procedure 618 maintains high fidelity predictions throughout service life. It replaces initial assumptions with observed data, providing customized state of health tracking. The combination of lab testing and in-situ calibration enables robust modeling across the battery lifetime.

### Example Vehicle Overview

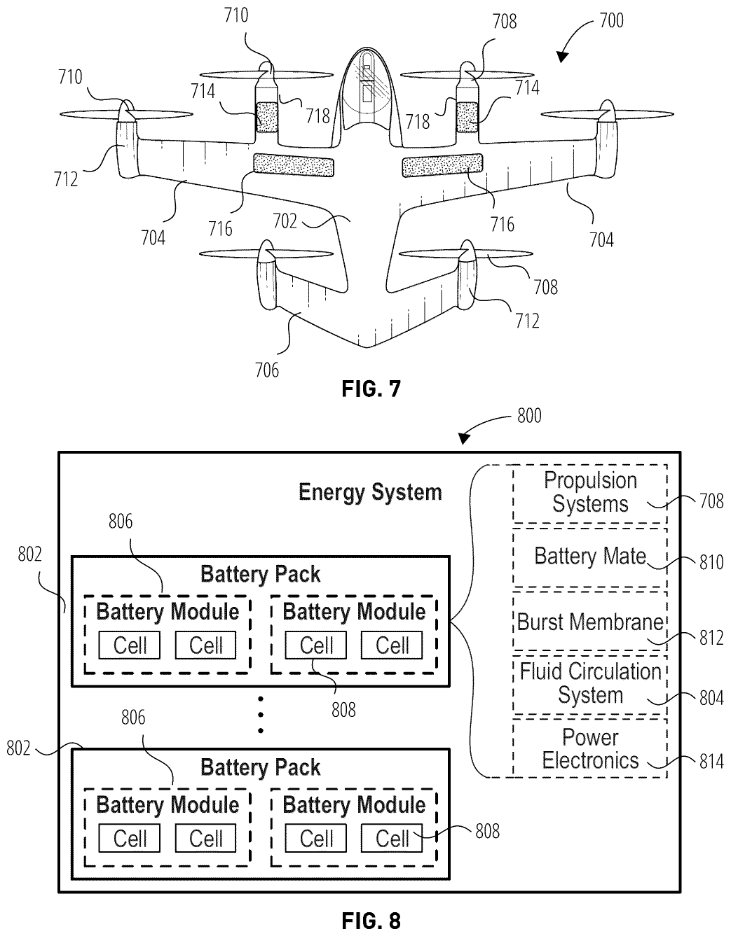

FIG. 7 is a plan view of a vertical takeoff and landing (VTOL) aircraft 700 according to some examples, which may comprise the electric aircraft 104. The aircraft 700 includes a fuselage 702, two wings 704, an empennage 706, and propulsion systems 708 embodied as tiltable rotor assemblies 710 located in nacelles 712. The aircraft 700 includes one or more nonlinear and isolated power sources in the example form of battery packs 802 embodied in FIG. 7 as nacelle battery packs 714 and wing battery packs 716. In the illustrated example, the nacelle battery packs 714 are located in inboard nacelles 718, but it will be appreciated that the nacelle battery packs 714 could be located in other nacelles 712 forming part of the aircraft 700. The aircraft 700 will typically include associated equipment such as an electronic infrastructure, control surfaces, a cooling system, landing gear, and so forth.

The wings 704 function to generate lift to support the aircraft 700 during forward flight. The wings 704 can additionally or alternately function to structurally support the battery packs 802, battery module 806 and/or propulsion systems 708 under the influence of various structural stresses (e.g., aerodynamic forces, gravitational forces, propulsive forces, external point loads, distributed loads, and/or body forces, and so forth).

### Energy Storage System

FIG. 8 is a schematic view of an aircraft energy storage system 800 according to some examples, which may be managed by the EMS 242. As shown, the energy storage system 800 includes one or more battery packs 802. Each battery pack 802 may include one or more battery modules 806, which in turn may comprise several cells 808.

Typically associated with a battery pack 802 are one or more propulsion systems 708, a battery mate 810 for connecting it to the energy storage system 800, a burst membrane 812 as part of a venting system, a fluid circulation system 804 for cooling, and power electronics 814 for regulating delivery of electrical power (from the battery during operation and to the battery during charging) and to provide integration of the battery pack 802 with the electronic infrastructure of the energy storage system 800. As discussed above, the propulsion systems 708 may comprise multiple tiltable rotor assemblies 710.

The electronic infrastructure and the power electronics 814 can additionally or alternately function to integrate the battery packs 802 into the energy storage system 800 of the aircraft. The electronic infrastructure can include the BMS 220, power electronics (HV architecture, power components, and so forth), LV architecture (e.g., vehicle wire harness, data connections, and so forth), and/or any other suitable components. The electronic infrastructure can include inter-module electrical connections, which can transmit power and/or data between battery packs and/or modules. Inter-modules can include bulkhead connections, bus bars, wire harnessing, and/or any other suitable components.

The battery packs 802 function to store electrochemical energy in a rechargeable manner for supply to the propulsion systems 708. Battery packs 802 can be arranged and/or distributed about the aircraft in any suitable manner. Battery packs can be arranged within wings (e.g., inside of an airfoil cavity), inside nacelles, and/or in any other suitable location on the aircraft. In a specific example, the energy storage system 800 includes a first battery pack within an inboard portion of a left wing and a second battery pack within an inboard portion of a right wing. In a second specific example, the system includes a first battery pack within an inboard nacelle of a left wing and a second battery pack within an inboard nacelle of a right wing. Battery packs 802 may include a plurality of battery modules 806.

The energy storage system 800 includes a cooling system (e.g., fluid circulation system 804) that functions to circulate a working fluid within the battery pack 802 to remove heat generated by the battery pack 802 during operation or charging. Battery cells 808, battery module 806 and/or battery packs 802 can be fluidly connected by the cooling system in series and/or parallel in any suitable manner.

### Computer System

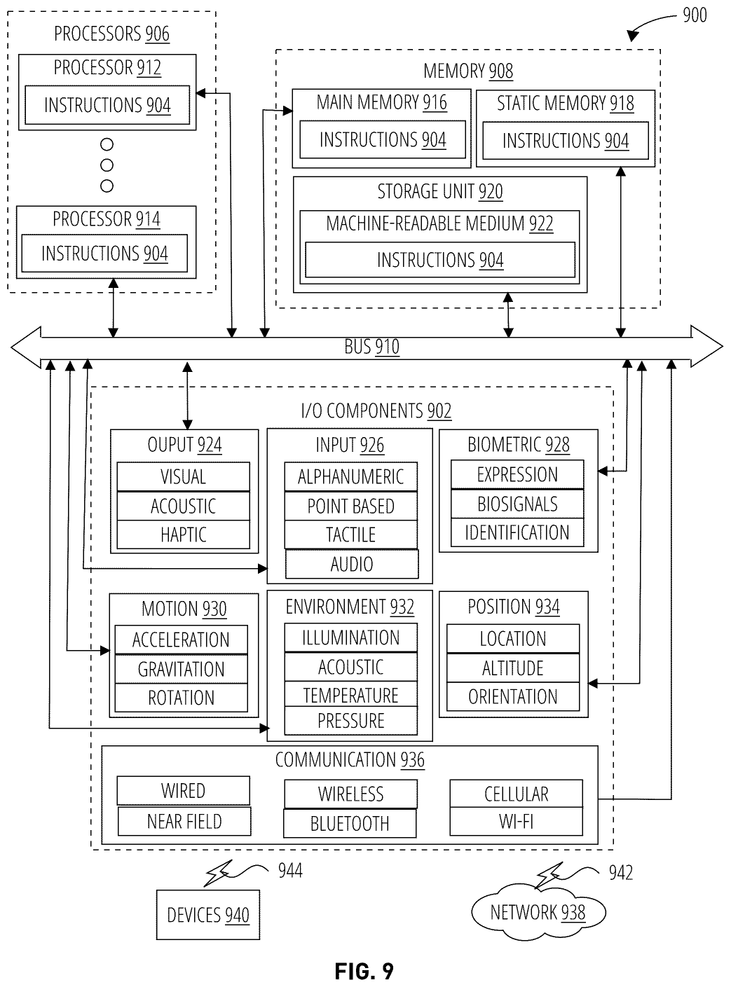

FIG. 9 shows a diagrammatic representation of the machine 900 in the example form of a computer system (such as, by way of example, the EMS flight control computer 228 or the system controller 136) within which instructions 904 (e.g., software, a program, an application, an applet, an app, or other executable code) for causing the machine 900 to perform any one or more of the methodologies discussed herein may be executed. The instructions 904 may transform the general, non-programmed machine 900 into a particular machine 900 programmed to carry out the described and illustrated functions in the manner described. In alternative examples, the machine 900 operates as a standalone device or may be coupled (e.g., networked) to other machines. In a networked deployment, the machine 900 may operate in the capacity of a server machine or a client machine in a server-client network environment, or as a peer machine in a peer-to-peer (or distributed) network environment. Further, while only a single machine 900 is illustrated, the term “machine” shall also be taken to include a collection of machines 900 that individually or jointly execute the instructions 904 to perform any one or more of the methodologies discussed herein.

The machine 900 may include processors 906, memory 908, and I/O components 902, which may be configured to communicate with each other such as via a bus 910. In an example, the processors 906 (e.g., a Central Processing Unit (CPU), a Reduced Instruction Set Computing (RISC) processor, a Complex Instruction Set Computing (CISC) processor, a Graphics Processing Unit (GPU), a Digital Signal Processor (DSP), an ASIC, a Radio-Frequency Integrated Circuit (RFIC), another processor, or any suitable combination thereof) may include, for example, a processor 912 and a processor 914 that may execute the instructions 904. The term “processor” is intended to include multi-core processors that may comprise two or more independent processors (sometimes referred to as “cores”) that may execute instructions contemporaneously. Although FIG. 9 shows multiple processors 906, the machine 900 may include a single processor with a single core, a single processor with multiple cores (e.g., a multi-core processor), multiple processors with a single core, multiple processors with multiples cores, or any combination thereof.

The memory 908 may include a main memory 916, a static memory 918, and a storage unit 920, both accessible to the processors 906 such as via the bus 910. The main memory 908, the static memory 918, and storage unit 920 store the instructions 904 embodying any one or more of the methodologies or functions described herein. The instructions 904 may also reside, completely or partially, within the main memory 916, within the static memory 918, within machine-readable medium 922 within the storage unit 920, within at least one of the processors 906 (e.g., within the processor's cache memory), or any suitable combination thereof, during execution thereof by the machine 900.

The I/O components 902 may include a wide variety of components to receive input, provide output, produce output, transmit information, exchange information, capture measurements, and so on. The specific I/O components 902 that are included in a particular machine will depend on the type of machine. For example, portable machines such as mobile phones will likely include a touch input device or other such input mechanisms, while a headless server machine will likely not include such a touch input device. It will be appreciated that the I/O components 902 may include many other components that are not shown in FIG. 9.

The I/O components 902 are grouped according to functionality merely for simplifying the following discussion and the grouping is in no way limiting. In various examples, the I/O components 902 may include output components 924 and input components 926. The output components 924 may include visual components (e.g., a display such as a plasma display panel (PDP), a light emitting diode (LED) display, a liquid crystal display (LCD), a projector, or a cathode ray tube (CRT)), acoustic components (e.g., speakers), haptic components (e.g., a vibratory motor, resistance mechanisms), other signal generators, and so forth. The input components 926 may include alphanumeric input components (e.g., a keyboard, a touch screen configured to receive alphanumeric input, a photo-optical keyboard, or other alphanumeric input components), point-based input components (e.g., a mouse, a touchpad, a trackball, a joystick, a motion sensor, or another pointing instrument), tactile input components (e.g., a physical button, a touch screen that provides location and/or force of touches or touch gestures, or other tactile input components), audio input components (e.g., a microphone), and the like.

In further examples, the I/O components 902 may include biometric components 928, motion components 930, environmental components 932, or position components 934, among a wide array of other components. For example, the biometric components 928 may include components to detect expressions (e.g., hand expressions, facial expressions, vocal expressions, body gestures, or eye tracking), measure biosignals (e.g., blood pressure, heart rate, body temperature, perspiration, or brain waves), identify a person (e.g., voice identification, retinal identification, facial identification, fingerprint identification, or electroencephalogram-based identification), and the like. The motion components 930 may include acceleration sensor components (e.g., accelerometer), gravitation sensor components, rotation sensor components (e.g., gyroscope), and so forth. The environmental components 932 may include, for example, illumination sensor components (e.g., photometer), temperature sensor components (e.g., one or more thermometers that detect ambient temperature), humidity sensor components, pressure sensor components (e.g., barometer), acoustic sensor components (e.g., one or more microphones that detect background noise), proximity sensor components (e.g., infrared sensors that detect nearby objects), gas sensors (e.g., gas detection sensors to detection concentrations of hazardous gases for safety or to measure pollutants in the atmosphere), or other components that may provide indications, measurements, or signals corresponding to a surrounding physical environment. The position components 934 may include location sensor components (e.g., a GPS receiver component), altitude sensor components (e.g., altimeters or barometers that detect air pressure from which altitude may be derived), orientation sensor components (e.g., magnetometers), and the like.

Communication may be implemented using a wide variety of technologies. The I/O components 902 may include communication components 936 operable to couple the machine 900 to a network 938 or devices 940 via a coupling 942 and a coupling 944, respectively. For example, the communication components 936 may include a network interface component or another suitable device to interface with the network 938. In further examples, the communication components 936 may include wired communication components, wireless communication components, cellular communication components, Near Field Communication (NFC) components, Bluetooth® components (e.g., Bluetooth® Low Energy), Wi-Fi® components, and other communication components to provide communication via other modalities. The devices 940 may be another machine or any of a wide variety of peripheral devices (e.g., a peripheral device coupled via a USB).

Moreover, the communication components 936 may detect identifiers or include components operable to detect identifiers. For example, the communication components 936 may include Radio Frequency Identification (RFID) tag reader components, NFC smart tag detection components, optical reader components (e.g., an optical sensor to detect one-dimensional bar codes such as Universal Product Code (UPC) bar code, multi-dimensional bar codes such as Quick Response (QR) code, Aztec code, Data Matrix, Dataglyph, MaxiCode, PDF417, Ultra Code, UCC RSS-2D bar code, and other optical codes), or acoustic detection components (e.g., microphones to identify tagged audio signals). In addition, a variety of information may be derived via the communication components 936, such as location via Internet Protocol (IP) geolocation, location via Wi-Fi® signal triangulation, location via detecting an NFC beacon signal that may indicate a particular location, and so forth.

### Executable Instructions and Machine Storage Medium

The various memories (i.e., memory 908, main memory 916, static memory 918, and/or memory of the processors 906) and/or storage unit 920 may store data, such as a battery model (e.g., the battery models 202), one or more sets of instructions and data structures embodying or utilized by any one or more of the methodologies or functions described herein. These instructions and models (e.g., the instructions 904), when executed by processors 906, cause various operations to implement the disclosed examples.

As used herein, the terms “machine-storage medium,” “device-storage medium,” “computer-storage medium” mean the same thing and may be used interchangeably in this disclosure. The terms refer to a single or multiple storage devices and/or media (e.g., a centralized or distributed database, and/or associated caches and servers) that store executable instructions and/or data. The terms shall accordingly be taken to include, but not be limited to, solid-state memories, and optical and magnetic media, including memory internal or external to processors. Specific examples of machine-storage media, computer-storage media and/or device-storage media include non-volatile memory, including by way of example semiconductor memory devices, e.g., erasable programmable read-only memory (EPROM), electrically erasable programmable read-only memory (EEPROM), FPGA, and flash memory devices; magnetic disks such as internal hard disks and removable disks; magneto-optical disks; and CD-ROM and DVD-ROM disks. The terms “machine-storage media,” “computer-storage media,” and “device-storage media” specifically exclude carrier waves, modulated data signals, and other such media, at least some of which are covered under the term “signal medium” discussed below.

### Transmission Medium

In various examples, one or more portions of the network 938 may be an ad hoc network, an intranet, an extranet, a VPN, a LAN, a WLAN, a WAN, a WWAN, a MAN, the Internet, a portion of the Internet, a portion of the PSTN, a plain old telephone service (POTS) network, a cellular telephone network, a wireless network, a Wi-Fi® network, another type of network, or a combination of two or more such networks. For example, the network 938 or a portion of the network 938 may include a wireless or cellular network, and the coupling 942 may be a Code Division Multiple Access (CDMA) connection, a Global System for Mobile communications (GSM) connection, or another type of cellular or wireless coupling. In this example, the coupling 942 may implement any of a variety of types of data transfer technology, such as Single Carrier Radio Transmission Technology (1×RTT), Evolution-Data Optimized (EVDO) technology, General Packet Radio Service (GPRS) technology, Enhanced Data rates for GSM Evolution (EDGE) technology, third Generation Partnership Project (3GPP) including 3G, fourth generation wireless (4G) networks, Universal Mobile Telecommunications System (UMTS), High Speed Packet Access (HSPA), Worldwide Interoperability for Microwave Access (WiMAX), Long Term Evolution (LTE) standard, others defined by various standard-setting organizations, other long range protocols, or other data transfer technology.

The instructions 904 may be transmitted or received over the network 938 using a transmission medium via a network interface device (e.g., a network interface component included in the communication components 936) and utilizing any one of many well-known transfer protocols (e.g., hypertext transfer protocol (HTTP)). Similarly, the instructions 904 may be transmitted or received using a transmission medium via the coupling 944 (e.g., a peer-to-peer coupling) to the devices 940. The terms “transmission medium” and “signal medium” mean the same thing and may be used interchangeably in this disclosure. The terms “transmission medium” and “signal medium” shall be taken to include any intangible medium that is capable of storing, encoding, or carrying the instructions 904 for execution by the machine 900, and includes digital or analog communications signals or other intangible media to facilitate communication of such software. Hence, the terms “transmission medium” and “signal medium” shall be taken to include any form of modulated data signal, carrier wave, and so forth. The term “modulated data signal” means a signal that has one or more of its characteristics set or changed in such a matter as to encode information in the signal.

### Computer-Readable Medium

The terms “machine-readable medium,” “computer-readable medium” and “device-readable medium” mean the same thing and may be used interchangeably in this disclosure. The terms are defined to include both machine-storage media and transmission media. Thus, the terms include both storage devices/media and carrier waves/modulated data signals.

### EXAMPLES

Example 1 is a method for calibrating a battery model for a battery of an electric aircraft, comprising: connecting the electric aircraft to ground support equipment to thermally condition the battery; testing the battery by loading the battery according to a load profile; continuously monitoring battery voltage, battery current, and battery temperature telemetry during testing to generate sensor data; analyzing the sensor data to obtain analyzed results; and updating the battery model based on the analyzed results.

In Example 2, the subject matter of Example 1 includes, wherein testing the battery further comprises loading the battery using a propulsion system of the electric aircraft.

In Example 3, the subject matter of Example 2 includes, wherein the propulsion system further comprises an electric motor connected to a propeller and loading the battery using the propulsion system further comprises ramping the propeller up or down based on the load profile.

In Example 4, the subject matter of Examples 1-3 includes, wherein testing the battery further comprises loading the battery using a power distribution system of the electric aircraft.

In Example 5, the subject matter of Example 4 includes, wherein loading the battery using a power distribution system further comprises charging or discharging the battery using a power supply of the power distribution system.

In Example 6, the subject matter of Examples 1-5 includes, generating a battery test plan by analyzing flight data for the electric aircraft, wherein the load profile load profile is specified by the battery test plan.

In Example 7, the subject matter of Example 6 includes, wherein testing the battery by loading the battery according to the load profile further comprises loading the battery according to the load profile specified by the test plan to create a target power draw for a specified duration that targets different power levels, temperatures, and charge states.

In Example 8, the subject matter of Examples 1-7 includes, wherein connecting the electric aircraft to ground support equipment to thermally condition battery further comprises circulating coolant around the battery to enable fast cooling of the battery during charging.

In Example 9, the subject matter of Examples 1-8 includes, wherein the battery includes a plurality of batteries and wherein testing the battery by loading the battery according to a load profile further comprises disconnecting some of the plurality of batteries from the loading to focus the loading on the remaining plurality of batteries during the testing.

Example 10 is a method for calibrating a battery model for battery packs powering an electric aircraft, comprising: connecting the electric aircraft to ground support equipment to thermally condition the battery packs; securing the electric aircraft to prevent movement during testing; selecting some of the battery packs to test to obtain selected battery packs; testing the selected battery packs by loading the selected battery packs with target power draws for a specified duration using at least one of: (a) a propeller that is part of a propulsion system of the electric aircraft; (b) a power distribution system of the electric aircraft; monitoring battery voltage, current, and temperature telemetry to generate telemetry data; performing additional testing by disconnecting some of the selected battery packs to increase loads on the remaining battery packs and adding data collect from these remaining battery packs to the telemetry data; and updating the battery model based on an analysis of the telemetry data.

In Example 11, the subject matter of Example 10 includes, selecting calibration test points to target gaps in flight data regarding battery pack performance.

In Example 12, the subject matter of Example 11 includes, providing resting periods between calibration test points for the battery packs being tested to stabilize.

In Example 13, the subject matter of Examples 11-12 includes, determining that additional calibration test points need to be completed; and selecting additional battery packs to test based on the additional calibration test points.

In Example 14, the subject matter of Examples 10-13 includes, wherein loading the selected battery packs further comprises ramping the propeller up and down using the propulsion system to create the target power draws for the specified duration.

Example 15 is a non-transitory computer-readable storage medium including instructions that when executed by a computer, cause the computer to perform operations for calibrating battery models for aircraft battery packs, comprising: receiving test points targeting gaps in calibration coverage; connecting the aircraft to ground support equipment, the ground support equipment including a rapid battery charging system; securing the aircraft to prevent movement during testing; selecting particular battery packs to test; ramping propellers to create target power draws for specified durations; activating selective battery packs including discharging a subset of battery packs to increase electrical loads on the selective battery packs during testing; monitoring battery voltage, current, and temperature telemetry to generate telemetry data; processing and storing the telemetry data; allowing resting periods between test points for batteries to stabilize; determining that additional test points need to be completed; selecting additional battery packs to test based on the determination; and updating the battery models based on analysis of the telemetry data.

In Example 16, the subject matter of Example 15 includes, wherein receiving test points includes analyzing flight data to identify gaps in calibration coverage across temperature, power level, state of charge (SOC), and charge/discharge.

In Example 17, the subject matter of Examples 15-16 includes, wherein selecting particular battery packs includes prioritizing testing of older packs.

In Example 18, the subject matter of Examples 15-17 includes, wherein ramping propellers includes modulating electric motor torque and RPM to control thrust.

In Example 19, the subject matter of Examples 15-18 includes, wherein allowing resting periods includes waiting for battery pack temperature to drop below a threshold.

In Example 20, the subject matter of Examples 15-19 includes, wherein updating the battery models includes tuning model parameters based on analysis of the telemetry data.

Example 21 is at least one machine-readable medium including instructions that, when executed by processing circuitry, cause the processing circuitry to perform operations to implement of any of Examples 1-20.

Example 22 is an apparatus comprising means to implement of any of Examples 1-20.

Example 23 is a system to implement of any of Examples 1-20.

Example 24 is a method to implement of any of Examples 1-20.

What is claimed is:

1. A method for calibrating a battery model for a battery of an electric aircraft, comprising:
connecting the electric aircraft to ground support equipment to thermally condition the battery;
testing the battery by loading the battery according to a load profile;
continuously monitoring battery voltage, battery current, and battery temperature telemetry during testing to generate sensor data;
analyzing the sensor data to obtain analyzed results; and
updating the battery model based on the analyzed results.

2. The method of claim 1, wherein testing the battery further comprises loading the battery using a propulsion system of the electric aircraft.

3. The method of claim 2, wherein the propulsion system further comprises an electric motor connected to a propeller and loading the battery using the propulsion system further comprises ramping the propeller up or down based on the load profile.

4. The method of claim 1, wherein testing the battery further comprises loading the battery using a power distribution system of the electric aircraft.

5. The method of claim 4, wherein loading the battery using a power distribution system further comprises charging or discharging the battery using a power supply of the power distribution system.

6. The method of claim 1, further comprising generating a battery test plan by analyzing flight data for the electric aircraft, wherein the load profile load profile is specified by the battery test plan.

7. The method of claim 6, wherein testing the battery by loading the battery according to the load profile further comprises loading the battery according to the load profile specified by the test plan to create a target power draw for a specified duration that targets different power levels, temperatures, and charge states.

8. The method of claim 1, wherein connecting the electric aircraft to ground support equipment to thermally condition battery further comprises circulating coolant around the battery to enable fast cooling of the battery during charging.

9. The method of claim 1, wherein the battery includes a plurality of batteries and wherein testing the battery by loading the battery according to a load profile further comprises disconnecting some of the plurality of batteries from the loading to focus the loading on the remaining plurality of batteries during the testing.

10. A method for calibrating a battery model for battery packs powering an electric aircraft, comprising:
connecting the electric aircraft to ground support equipment to thermally condition the battery packs;
securing the electric aircraft to prevent movement during testing;
selecting some of the battery packs to test to obtain selected battery packs;
testing the selected battery packs by loading the selected battery packs with target power draws for a specified duration using at least one of: (a) a propeller that is part of a propulsion system of the electric aircraft; (b) a power distribution system of the electric aircraft;
monitoring battery voltage, current, and temperature telemetry to generate telemetry data;
performing additional testing by disconnecting some of the selected battery packs to increase loads on the remaining battery packs and adding data collect from these remaining battery packs to the telemetry data; and
updating the battery model based on an analysis of the telemetry data.

11. The method of claim 10, further comprising selecting calibration test points to target gaps in flight data regarding battery pack performance.

12. The method of claim 11, further comprising providing resting periods between calibration test points for the battery packs being tested to stabilize.

13. The method of claim 11, further comprising:
determining that additional calibration test points need to be completed; and
selecting additional battery packs to test based on the additional calibration test points.

14. The method of claim 10, wherein loading the selected battery packs further comprises ramping the propeller up and down using the propulsion system to create the target power draws for the specified duration.

15. A non-transitory computer-readable storage medium including instructions that when executed by a computer, cause the computer to perform operations for calibrating battery models for aircraft battery packs, comprising:
receiving test points targeting gaps in calibration coverage;
connecting the aircraft to ground support equipment, the ground support equipment including a rapid battery charging system;
securing the aircraft to prevent movement during testing;
selecting particular battery packs to test;
ramping propellers to create target power draws for specified durations;
activating selective battery packs including discharging a subset of battery packs to increase electrical loads on the selective battery packs during testing;
monitoring battery voltage, current, and temperature telemetry to generate telemetry data;
processing and storing the telemetry data;
allowing resting periods between test points for batteries to stabilize;
determining that additional test points need to be completed;
selecting additional battery packs to test based on the determination; and
updating the battery models based on analysis of the telemetry data.

16. The computer-readable storage medium of claim 15, wherein receiving test points includes analyzing flight data to identify gaps in calibration coverage across temperature, power level, state of charge (SOC), and charge/discharge.

17. The computer-readable storage medium of claim 15, wherein selecting particular battery packs includes prioritizing testing of older packs.

18. The computer-readable storage medium of claim 15, wherein ramping propellers includes modulating electric motor torque and RPM to control thrust.

19. The computer-readable storage medium of claim 15, wherein allowing resting periods includes waiting for battery pack temperature to drop below a threshold.

20. The computer-readable storage medium of claim 15, wherein updating the battery models includes tuning model parameters based on analysis of the telemetry data.
